(19) United States
(12) Patent Application Publication
(10) Pub. No.: US 2020/0266266 A1
(43) Pub. Date: Aug. 20, 2020

(54) SEMICONDUCTOR DEVICE WITH HIGH CHARGE CARRIER MOBILITY MATERIALS ON POROUS SILICON

(71) Applicant: QUALCOMM lncorporated, San Diego, CA (US)

(72) Inventors: Sinan GOKTEPELI, San Diego, CA (US); Stephen Alan FANELLI, San Marcos, CA (US); Richard HAMMOND, Gwent (GB)

(21) Appl. No.: 16/802,504

(22) Filed: Feb. 26, 2020

Related U.S. Application Data
(62) Division of application No. 15/836,122, filed on Dec. 8, 2017.

(51) Int. Cl. H01L 29/04; H01L 21/02; H01L 27/092; H01L 21/8258; H01L 29/10; H01L 21/8238

(52) U.S. Cl. CPC H01L 29/045; H01L 21/02513; H01L 27/092; H01L 21/0245; H01L 21/02439; H01L 21/823807; H01L 21/02381; H01L 21/8258; H01L 21/02505; H01L 29/1054; H01L 27/0922; H01L 21/02521

(57) ABSTRACT

A semiconductor device includes a porous silicon layer on a silicon substrate. The semiconductor device also includes a seal layer on the porous silicon layer. The semiconductor device further includes a high charge carrier mobility material layer on the seal layer. The semiconductor device may further include a strain balancing intermediate layer between the seal layer and the high charge carrier mobility material layer. Different high charge carrier mobility materials can be used in the high charge carrier mobility material layer to form different semiconductor devices.

### PRIORITY APPLICATION

This application is a divisional application of U.S. Non-Provisional patent application Ser. No. 15/836,122, filed on Dec. 8, 2017, titled “SEMICONDUCTOR DEVICE WITH HIGH CHARGE CARRIER MOBILITY MATERIALS ON POROUS SILICON,” which is incorporated herein by reference in its entirety.

### BACKGROUND

### Field

Certain aspects of the present disclosure generally relate to integrated circuits (ICs), and more particularly, to semiconductor device with high charge carrier mobility materials on porous silicon.

### Background

In the past several decades, the semiconductor industry has continued to improve the performance of complementary metal oxide semiconductor (CMOS) transistors by scaling down the dimensions of the transistors. For example, one of the controlling factors of the speed of CMOS transistors is the time of the charge carriers travelling through the channel region under the gate of the transistor. Reducing the gate length shortens the charge carrier travel time, increasing the transistor's speed. However, as the dimension of the gate approaches the physical limitation in miniaturization of CMOS process, it becomes more difficult to further improve the performance of CMOS transistors.

An alternative approach to improve the performance of CMOS transistors employs high charge carrier mobility materials to replace silicon (Si) in the channel region of the transistor. High charge carrier mobility materials comprise materials with higher charge carrier mobility than that of Si, such as Germanium (Ge) and III-V materials (compounds of group III materials (e.g., Aluminum (Al), Gallium (Ga), and Indium (In)) and group V materials (e.g., Nitrogen (N), Phosphorus (P), Arsenic (As), and Antimony (Sb)) in the periodic table). Using high charge carrier mobility materials can result in higher speed of the charge carriers and can lead to relaxation on the dimension of the gate.

High charge carrier mobility materials are difficult to grow epitaxially on silicon substrate without defects, such as dislocations, due to lattice mismatch between high charge carrier mobility materials and Si. There have been experiments with growing high charge carrier mobility materials on silicon substrate using multiple buffer layers to gradually accommodate for the lattice mismatch. For example, a first buffer layer can be deposited on a silicon substrate. A second buffer layer can be deposited on the first buffer layer. High charge carrier mobility materials can be deposited on the second buffer layer. The second buffer layer may have lattice constant that matches lattice constants of the high charge carrier mobility materials. The first buffer layer may have lattice constant between lattice constant of the silicon substrate and the lattice constants of the high charge carrier mobility materials. Thus, the lattice constant changes gradually among the multiple layers to reduce defects in the high charge carrier mobility materials. However, cost of fabrication and defectivity remain to be the limiting factors on mass production.

Another approach to reduce defects in the high charge carrier mobility materials on silicon substrate is to grow the high charge carrier mobility materials in high aspect ratio trenches on the silicon substrate. The width of the high aspect ratio trenches is smaller compared to the height of the high aspect ratio trenches. Thus, defects growing along certain crystal planes can be confined at the bottom of the trench and cannot propagate to the top of the trench. However, defects growing along other crystal planes can still propagate to the top of the trench and create device killing defect paths. Thus, there is a need to develop a process to incorporate high charge carrier mobility materials with minimum defects on silicon substrate.

### SUMMARY

Certain aspects of the present disclosure provide a semiconductor device. The semiconductor device may include a porous silicon layer on a silicon substrate. The semiconductor device may also include a seal layer on the porous silicon layer and a high charge carrier mobility material layer on the seal layer.

Certain aspects of the present disclosure provide a semiconductor device. The semiconductor device may include a porous silicon layer on a silicon substrate. The semiconductor device may also include a strain balancing intermediate layer on the porous silicon layer and a high charge carrier mobility material layer on the strain balancing intermediate layer.

Certain aspects of the present disclosure provide a method for fabricating a semiconductor device. The method may include forming a porous silicon layer on a silicon substrate and forming a seal layer on the porous silicon layer. The method may also include forming a high charge carrier mobility material layer on the seal layer.

This summary has outlined, rather broadly, the features and embodiments of the present disclosure so that the following detailed description may be better understood. Additional features and embodiments of the present disclosure will be described below. It should be appreciated by those skilled in the art that this disclosure may be readily utilized as a basis for modifying or designing other equivalent structures for carrying out the same purposes of the present disclosure. It should also be realized by those skilled in the art that such equivalent constructions do not depart from the teachings of the present disclosure as set forth in the appended claims. The features, which are believed to be characteristic of the present disclosure, both as to its organization and method of operation, will be better understood from the following description when considered in connection with the accompanying figures. It is to be expressly understood, however, that each of the figures is provided for the purpose of illustration and description only and is not intended as a definition of the limits of the present disclosure.

### BRIEF DESCRIPTION OF THE DRAWINGS

FIG. 1A is a cross-sectional diagram of an exemplary semiconductor device with high charge carrier mobility materials formed on a silicon substrate with a porous silicon layer in accordance with certain aspects of the present disclosure;

FIG. 1B is a cross-sectional diagram of another exemplary semiconductor device with high charge carrier mobility materials formed on a silicon substrate with a porous silicon layer in accordance with certain aspects of the present disclosure;

FIG. 2A provides a flow chart illustrating an exemplary fabrication process for the semiconductor device of FIG. 1A in accordance with certain aspects of the present disclosure;

FIG. 2B provides cross-sectional diagrams of the semiconductor device of FIG. 1A at each stage of the process of fabrication in FIG. 2A;

FIG. 3A provides a flow chart illustrating an exemplary fabrication process for the semiconductor device of FIG. 1B in accordance with certain aspects of the present disclosure;

FIG. 3B provides cross-sectional diagrams of the semiconductor device of FIG. 1B at each stage of the process of fabrication in FIG. 3A;

FIG. 4 is a cross-sectional diagram of an exemplary semiconductor device with high charge carrier mobility materials formed on a silicon substrate with a porous silicon layer in accordance with certain aspects of the present disclosure;

FIG. 5 provides a flow chart illustrating an exemplary fabrication process for the semiconductor device of FIG. 4 in accordance with certain aspects of the present disclosure;

FIGS. 6A-6B provide cross-sectional diagrams of the semiconductor device of FIG. 4 at each stage of the process of fabrication in FIG. 5;

FIG. 7 is a cross-sectional diagram of an exemplary semiconductor device with high charge carrier mobility materials formed on a silicon substrate with a porous silicon layer in accordance with certain aspects of the present disclosure;

FIG. 8 provides a flow chart illustrating an exemplary fabrication process for the semiconductor device of FIG. 7 in accordance with certain aspects of the present disclosure;

FIGS. 9A-9C provide cross-sectional diagrams of the semiconductor device of FIG. 7 at each stage of the process of fabrication in FIG. 8; and

FIG. 10 is a block diagram showing an exemplary wireless communication system in which an aspect of the present disclosure may be employed.

### DETAILED DESCRIPTION

With reference to the drawing figures, several exemplary aspects of the present disclosure are described. The word “exemplary” is used herein to mean “serving as an example, instance, or illustration.” Any aspect described herein as “exemplary” is not necessarily to be construed as preferred or advantageous over other aspects. As detailed herein, the term “on” used throughout this description means “directly on” in some aspects (e.g., directly in contact), and “indirectly on” in other aspects (e.g., an intermediate layer in between).

The detailed description set forth below, in connection with the appended drawings, is intended as a description of various aspects and is not intended to represent the only aspect in which the concepts described herein may be practiced. The detailed description includes specific details for the purpose of providing a thorough understanding of the various concepts. It will be apparent to those skilled in the art, however, that these concepts may be practiced without these specific details. In some instances, well-known structures and components are shown in block diagram form in order to avoid obscuring such concepts.

Aspects disclosed in the detailed description include high charge carrier mobility materials formed on a silicon substrate with a porous silicon layer for complementary metal oxide semiconductor (CMOS) transistor applications. High charge carrier mobility materials comprise materials with higher charge carrier mobility than that of silicon (Si), such as Germanium (Ge) and III-V materials (compounds of group III materials and group V materials in the periodic table, e.g., Gallium Arsenide (GaAs), Indium Gallium Arsenide (InGaAs), Indium Gallium Phosphide (InGaP), and Gallium Nitride (GaN)). In certain aspects, a semiconductor device includes a porous silicon layer on a silicon substrate. The semiconductor device also includes a seal layer on the porous silicon layer. The seal layer is a thin layer on the porous silicon layer so that the seal layer can stretch or compress freely. Thus, the seal layer provides a relaxing surface to form a high charge carrier mobility material layer on the seal layer. As a result, the high charge carrier mobility material layer formed on the seal layer is relaxed, which prevents formation of defects, such as dislocations in the high charge carrier mobility material layer, even though lattice constant of the high charge carrier mobility material layer is different from lattice constant of the seal layer. By incorporating the porous silicon layer and the thin seal layer, high charge carrier mobility materials in the high charge carrier mobility material layer can grow with lower defect concentrations. In another aspect, the semiconductor device further includes a strain balancing intermediate layer (SBIL) between the seal layer and the high charge carrier mobility material layer. The SBIL may have lattice constant closer to the lattice constant of the high charge carrier mobility material layer compared to lattice constant of Si. Thus, the high charge carrier mobility material layer formed on the SBIL may have lower defect concentrations compared with the high charge carrier mobility material layer formed directly on Si. The high charge carrier mobility material layer formed according to certain aspects of the present disclosure can be used to form different CMOS transistors.

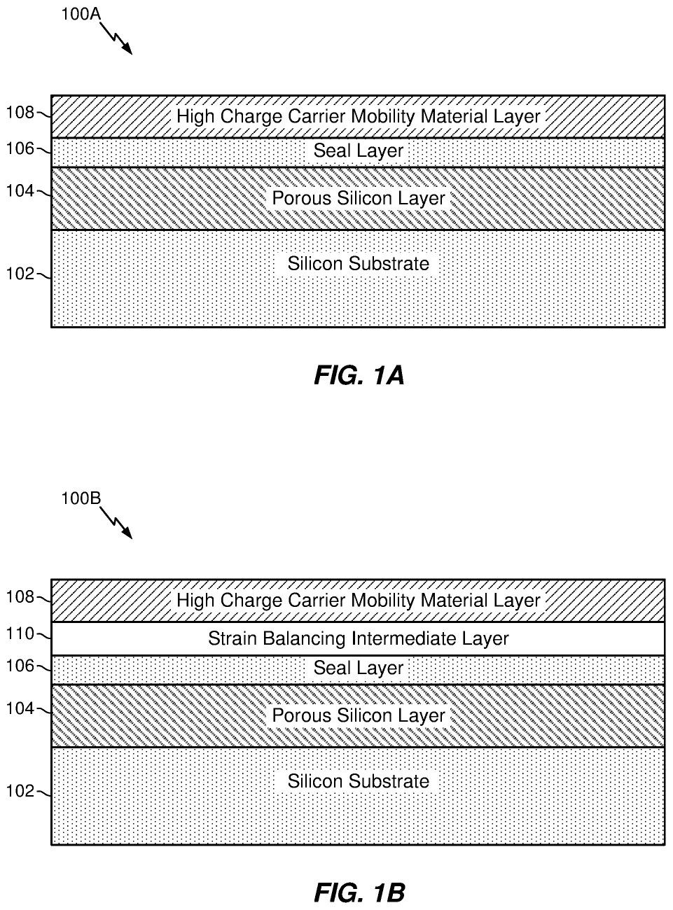

In this regard, FIG. 1A illustrates an exemplary semiconductor device with high charge carrier mobility materials formed on a silicon substrate with a porous silicon layer in accordance with certain aspects of the present disclosure. A semiconductor device 100A is shown in FIG. 1A, which comprises different layers of materials on a silicon substrate 102. The silicon substrate 102 is a single crystal silicon substrate. A porous silicon layer 104 is on the silicon substrate 102. Porous silicon may be formed by electrochemical etching of single crystal silicon in solutions containing hydrofluoric acid (HF). Porous silicon is a form of silicon with nanopores or micropores in its structure, resulting in a large surface to volume ratio.

With continuing reference to FIG. 1A, a seal layer 106 is on the porous silicon layer 104. The seal layer 106 may be a thin seal layer comprising silicon. The seal layer 106 has a single crystal structure with a uniform surface. As an example, a thickness of the seal layer 106 is in the range of 10 to 30 angstroms. The seal layer 106 provides a relaxing surface to form a high charge carrier mobility material layer 108 on the seal layer 106. The high charge carrier mobility material layer 108 comprises Ge or III-V materials, such as GaAs, InGaAs, InGaP, and GaN. Because the seal layer 106 is a thin layer on the porous silicon layer 104, the seal layer 106 can stretch or compress freely. As a result, the high charge carrier mobility material layer 108 formed on the seal layer 106 is relaxed, which prevents formation of defects, such as dislocations in the high charge carrier mobility material layer 108, even though lattice constant of the high charge carrier mobility material layer 108 is different from lattice constant of the seal layer 106.

As mentioned in the background, growth of high charge carrier mobility materials directly on a silicon substrate reduces the quality of the high charge carrier mobility materials by creating high defect concentrations. By incorporating the porous silicon layer 104 and the thin seal layer 106, the high charge carrier mobility materials in the high charge carrier mobility material layer 108 are relaxed when they grow on the seal layer 106, resulting in the high charge carrier mobility material layer 108 having lower defect concentrations. The high charge carrier mobility material layer 108 can be used to form different CMOS transistors.

FIG. 1B illustrates another exemplary semiconductor device with high charge carrier mobility materials formed on a silicon substrate with a porous silicon layer in accordance with certain aspects of the present disclosure. A semiconductor device 100B is shown in FIG. 1B, which comprises different layers of materials on a silicon substrate 102. The silicon substrate 102 is a single crystal silicon substrate. A porous silicon layer 104 is on the silicon substrate 102.

With continuing reference to FIG. 1B, a seal layer 106 is on the porous silicon layer 104. The seal layer 106 may be a thin seal layer comprising silicon. The seal layer 106 has a single crystal structure with a uniform surface. As an example, a thickness of the seal layer 106 is in the range of 10 to 30 angstroms. The seal layer 106 provides a relaxing surface to form an SBIL 110 on the seal layer 106. The SBIL 110 comprises strain balancing materials, such as Silicon Germanium (SiGe) (SiGe may comprise 20%-60% Ge as an example), Silicon Carbide (SiC) (SiC may comprise 0.1%-2% C as an example), and alloys of Si and III-V materials. As an example, a thickness of the SBIL 110 is in the range of 100 to 500 angstroms. Because the seal layer 106 is a thin layer on the porous silicon layer 104, the seal layer 106 can stretch or compress freely. As a result, the SBIL 110 formed on the seal layer 106 is relaxed, which prevents formation of defects, such as dislocations in the SBIL 110, even though lattice constant of the SBIL 110 is different from lattice constant of the seal layer 106.

The strain balancing materials in the SBIL 110 may have lattice constants closer to lattice constants of high charge carrier mobility materials compared to lattice constant of Si. Thus, the high charge carrier mobility materials formed on the SBIL 110 may have lower defect concentrations compared with the high charge carrier mobility materials formed directly on Si. As an example, lattice constant of SiGe is higher than the lattice constant of Si, such that SiGe can be used as strain balancing materials for high charge carrier mobility materials with higher lattice constant than that of Si (e.g., Ge, GaAs, InGaAs, InGaP, and GaN). Lattice constant of SiC is lower than the lattice constant of Si, such that SiC can be used as strain balancing materials for high charge carrier mobility materials with lower lattice constant than that of Si. Thus, the SBIL 110 may act as a buffer between the seal layer 106 and the high charge carrier mobility materials to gradually change the lattice constant among different layers.

With continuing reference to FIG. 1B, a high charge carrier mobility material layer 108 is on the SBIL 110. Because the SBIL 110 is relaxed and defect free as explained above, the quality of the high charge carrier mobility material layer 108 formed on the SBIL 110 can be enhanced. Additionally, the lattice constant of the SBIL 110 is closer to lattice constant of the high charge carrier mobility material layer 108 compared to the lattice constant of Si. Thus, the high charge carrier mobility material layer 108 formed on the SBIL 110 may have lower defect concentrations compared with the high charge carrier mobility material layer 108 formed directly on Si. If the SBIL 110 comprises SiGe, the high charge carrier mobility material layer 108 may comprise high charge carrier mobility materials with higher lattice constant than that of Si. If the SBIL 110 comprises SiC, the high charge carrier mobility material layer 108 may comprise high charge carrier mobility materials with lower lattice constant than that of Si. By employing different strain balancing materials, different high charge carrier mobility materials can be used in the high charge carrier mobility material layer 108 to form different CMOS transistors.

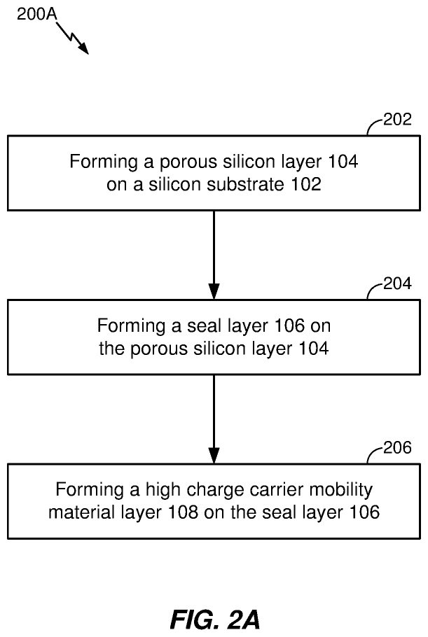

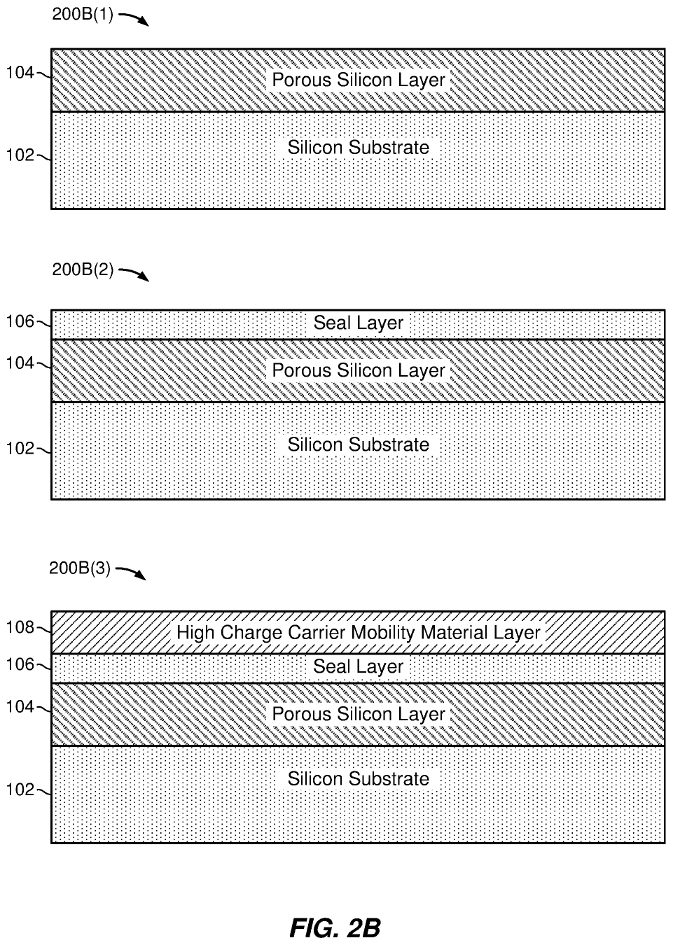

FIG. 2A illustrates an exemplary fabrication process 200A for the semiconductor device 100A in FIG. 1A in accordance with certain aspects of the present disclosure. FIG. 2B provides cross-sectional diagrams of the semiconductor device 100A of FIG. 1A illustrating respective stages 200B(1)-200B(3) of the fabrication process 200A in FIG. 2A. The cross-sectional diagrams illustrating the semiconductor device 100A in FIG. 2B will be discussed in conjunction with the discussion of the exemplary steps in the fabrication process 200A in FIG. 2A.

In this regard, the fabrication process 200A in FIG. 2A includes forming a porous silicon layer 104 on a single crystal silicon substrate 102 (block 202, stage 200B(1) of FIG. 2B). As an example, the porous silicon layer 104 can be obtained by electrochemical etching of the silicon substrate 102 in organic solutions of acetonitrile (CH₃CN) or dimethylformamide (C₃H₇NO) together with HF. An alternative approach is to chemically etch the silicon substrate 102 in a mixture of HF and nitric acid (HNO₃) to produce the porous silicon layer 104.

The fabrication process 200A further includes forming a seal layer 106 on the porous silicon layer 104 (block 204, stage 200B(2) of FIG. 2B). As an example, the seal layer 106 can be obtained by high temperature annealing of the porous silicon layer 104 in a hydrogen (H₂) environment. High temperature annealing in H₂ will close pores on the porous silicon layer 104 and form a thin single crystal layer (the seal layer 106) with uniform surface. An alternative approach is to perform high temperature oxidation on the porous silicon layer 104. High temperature oxidation will form a thin single crystal layer (the seal layer 106) on the porous silicon layer 104 with an oxide layer on top of the seal layer 106. By removing the oxide layer, the seal layer 106 will be exposed.

Next, the fabrication process 200A includes forming a high charge carrier mobility material layer 108 on the seal layer 106 (block 206, stage 200B(3) of FIG. 2B). As an example, the high charge carrier mobility material layer 108 can be obtained by epitaxial growth of high charge carrier mobility materials on the seal layer 106. The seal layer 106 is a thin layer on the porous silicon layer 104. Thus, the seal layer 106 can stretch or compress freely. The high charge carrier mobility material layer 108 formed on the seal layer 106 is relaxed, which prevents formation of defects, such as dislocations in the high charge carrier mobility material layer 108, even though lattice constant of the high charge carrier mobility material layer 108 is different from lattice constant of the seal layer 106. As a result, the high charge carrier mobility material layer 108 may have lower defect concentrations. The high charge carrier mobility material layer 108 can be used to improve charge carrier mobility in different CMOS transistors. Following the fabrication process 200A, standard CMOS process flow can be used to form various CMOS devices, such as transistors, from the semiconductor device 100A.

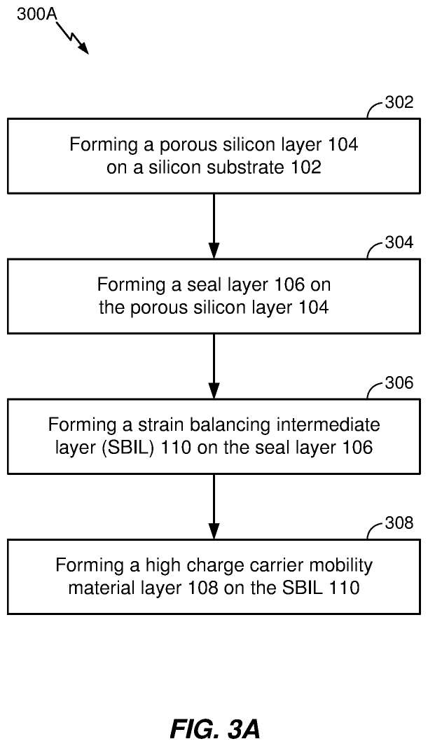

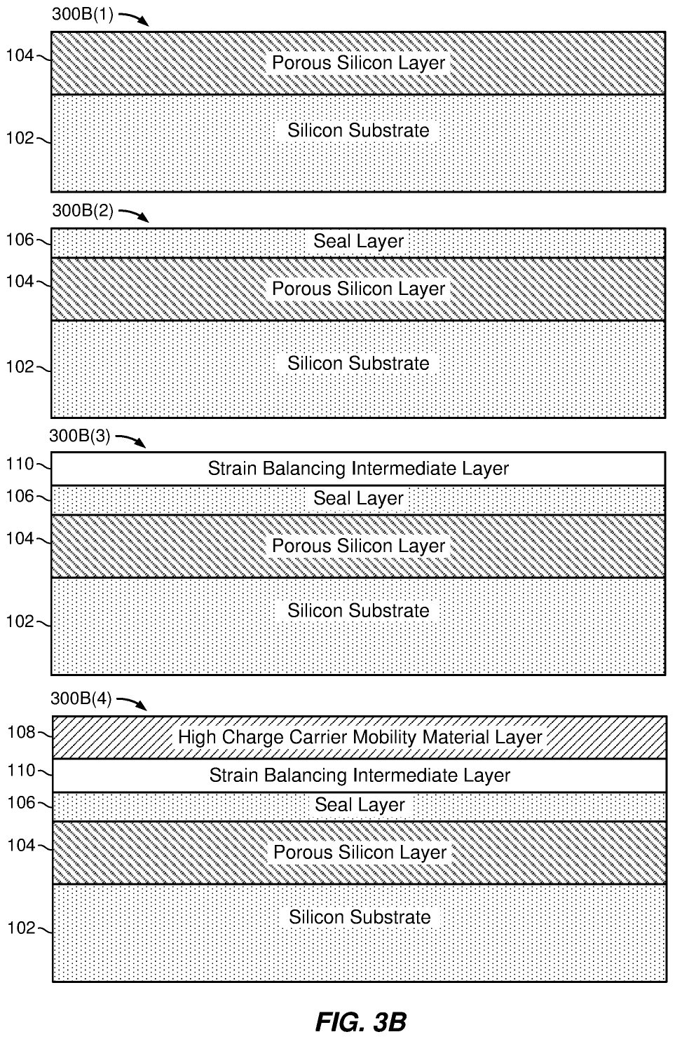

FIG. 3A illustrates an exemplary fabrication process 300A for the semiconductor device 100B in FIG. 1B in accordance with certain aspects of the present disclosure. FIG. 3B provides cross-sectional diagrams of the semiconductor device 100B of FIG. 1B illustrating respective stages 300B(1)-300B(4) of the fabrication process 300A in FIG. 3A. The cross-sectional diagrams illustrating the semiconductor device 100B in FIG. 3B will be discussed in conjunction with the discussion of the exemplary steps in the fabrication process 300A in FIG. 3A.

In this regard, the fabrication process 300A in FIG. 3A includes forming a porous silicon layer 104 on a single crystal silicon substrate 102 (block 302, stage 300B(1) of FIG. 3B). As an example, the porous silicon layer 104 can be obtained by electrochemical etching of the silicon substrate 102 in organic solutions of CH₃CN or C₃H₇NO together with HF. An alternative approach is to chemically etch the silicon substrate 102 in a mixture of HF and HNO₃ to produce the porous silicon layer 104.

The fabrication process 300A also includes forming a seal layer 106 on the porous silicon layer 104 (block 304, stage 300B(2) of FIG. 3B). As an example, the seal layer 106 can be obtained by high temperature annealing of the porous silicon layer 104 in an H₂ environment. High temperature annealing in H₂ will close pores on the porous silicon layer 104 and form a thin single crystal layer (the seal layer 106) with uniform surface. An alternative approach is to perform high temperature oxidation on the porous silicon layer 104. High temperature oxidation will form a thin single crystal layer (the seal layer 106) on the porous silicon layer 104 with an oxide layer on top of the seal layer 106. By removing the oxide layer, the seal layer 106 will be exposed.

The fabrication process 300A further includes forming an SBIL 110 on the seal layer 106 from strain balancing materials (e.g., SiGe and SiC) (block 306, stage 300B(3) of FIG. 3B). As an example, the SBIL 110 can be obtained by epitaxial growth of the strain balancing materials on the seal layer 106. The seal layer 106 is a thin layer on the porous silicon layer 104. Thus, the seal layer 106 can stretch or compress freely. The SBIL 110 formed on the seal layer 106 is relaxed, which prevents formation of defects, such as dislocations in the SBIL 110, and results in the SBIL 110 with lower defect concentrations, even though lattice constant of the SBIL 110 is different from lattice constant of the seal layer 106.

Next, the fabrication process 300A includes forming a high charge carrier mobility material layer 108 on the SBIL 110 (block 308, stage 300B(4) of FIG. 3B). As an example, the high charge carrier mobility material layer 108 can be obtained by epitaxial growth of high charge carrier mobility materials on the SBIL 110. As described above, the SBIL 110 is relaxed and defect free. Thus, the quality of the high charge carrier mobility material layer 108 formed on the SBIL 110 can be enhanced. Additionally, the lattice constant of the SBIL 110 is closer to lattice constant of the high charge carrier mobility material layer 108 compared to lattice constant of Si. Thus, the high charge carrier mobility material layer 108 formed on the SBIL 110 may have lower defect concentrations compared with the high charge carrier mobility material layer 108 formed directly on Si. If the SBIL 110 comprises SiGe, the high charge carrier mobility material layer 108 may comprise high charge carrier mobility materials with higher lattice constant than that of Si. If the SBIL 110 comprises SiC, the high charge carrier mobility material layer 108 may comprise high charge carrier mobility materials with lower lattice constant than that of Si. The high charge carrier mobility material layer 108 can be used to improve charge carrier mobility in different CMOS transistors. Following the fabrication process 300A, standard CMOS process flow can be used to form various CMOS devices, such as transistors, from the semiconductor device 100B.

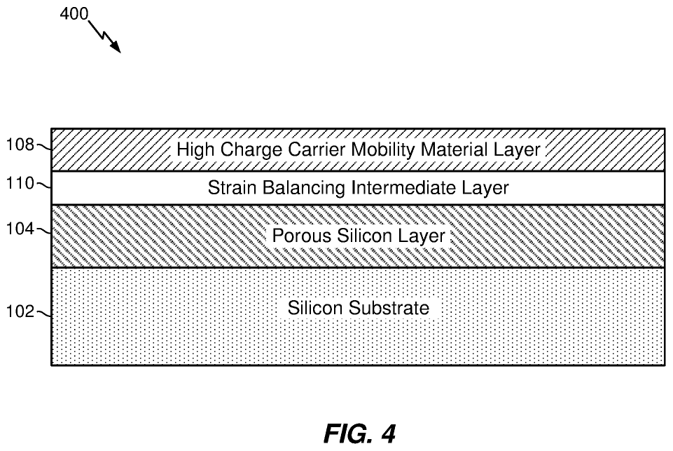

In addition to the semiconductor devices 100A and 100B described in FIG. 1A and FIG. 1B, FIG. 4 illustrates another exemplary semiconductor device 400 with high charge carrier mobility materials formed on a silicon substrate with a porous silicon layer in accordance with certain aspects of the present disclosure. The semiconductor device 400 includes common elements with the semiconductor devices 100A and 100B of FIG. 1A and FIG. 1B, which are referred to with common element numbers in FIG. 1A, FIG. 1B, and FIG. 4, and thus will not be re-described herein.

The semiconductor device 400 shown in FIG. 4 includes different layers of materials on a silicon substrate 102. A porous silicon layer 104 is on the silicon substrate 102. An SBIL 110 is on the porous silicon layer 104. A high charge carrier mobility material layer 108 is on the SBIL 110. Lattice constant of the SBIL 110 is closer to lattice constant of the high charge carrier mobility material layer 108 compared to lattice constant of Si. Thus, the high charge carrier mobility material layer 108 formed on the SBIL 110 may have lower defect concentrations compared with the high charge carrier mobility material layer 108 formed directly on Si. By employing different strain balancing materials, different high charge carrier mobility materials can be used in the high charge carrier mobility material layer 108 to form different CMOS transistors.

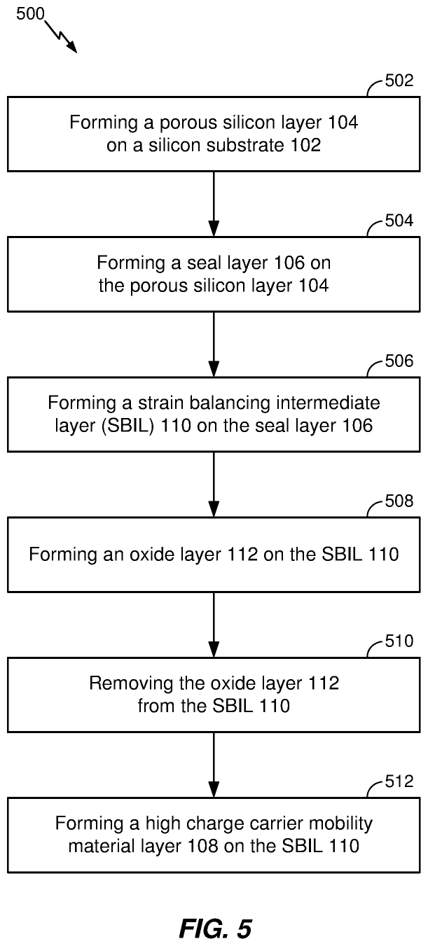

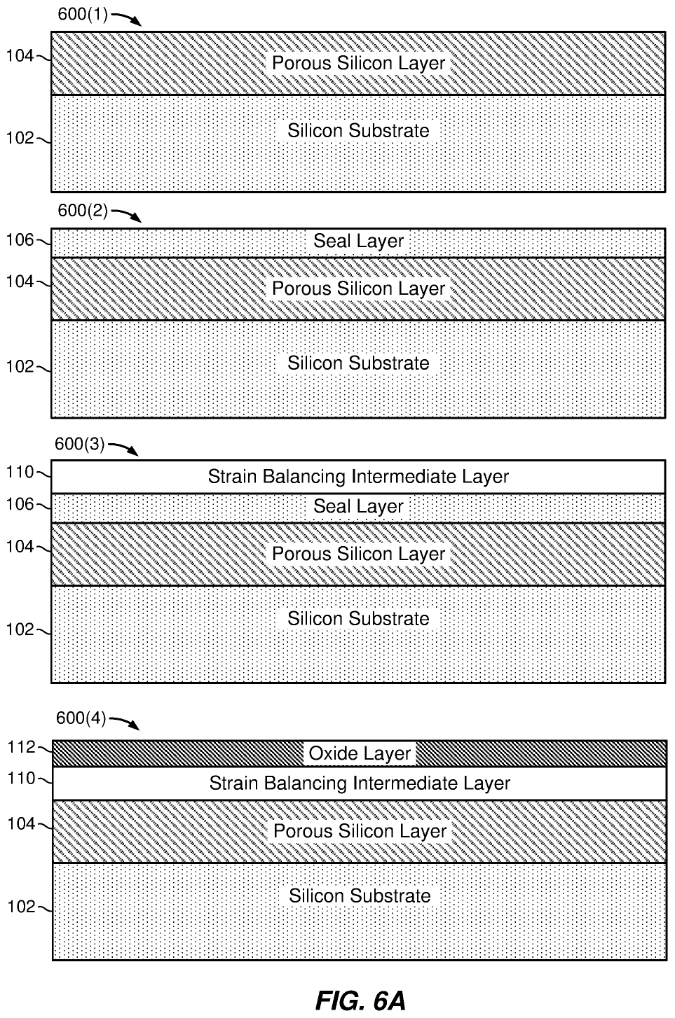

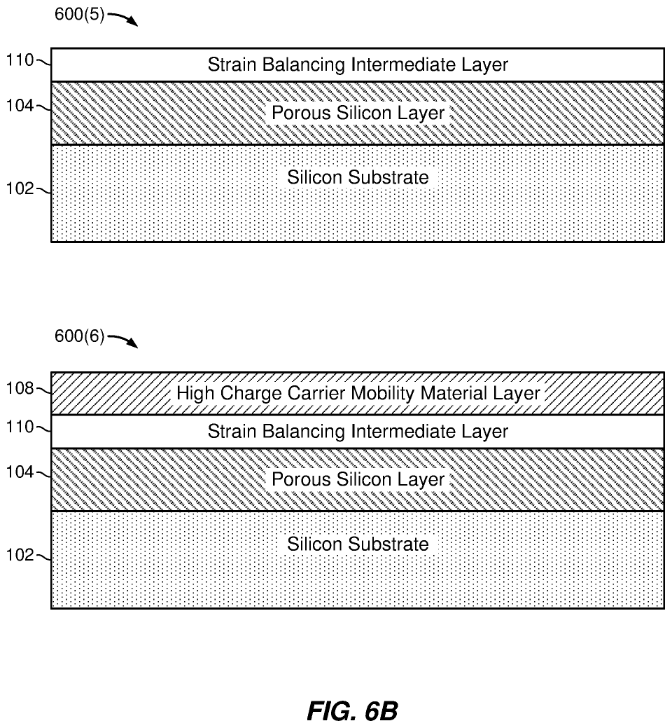

FIG. 5 illustrates an exemplary fabrication process 500 for the semiconductor device 400 in FIG. 4 in accordance with certain aspects of the present disclosure. FIGS. 6A-6B provide cross-sectional diagrams of the semiconductor device 400 of FIG. 4 illustrating respective stages 600(1)-600(6) of the fabrication process 500 in FIG. 5. The cross-sectional diagrams illustrating the semiconductor device 400 in FIGS. 6A-6B will be discussed in conjunction with the discussion of the exemplary steps in the fabrication process 500 in FIG. 5.

In this regard, the fabrication process 500 in FIG. 5 includes forming a porous silicon layer 104 on a single crystal silicon substrate 102 (block 502, stage 600(1) of FIG. 6A). As an example, the porous silicon layer 104 can be obtained by electrochemical etching of the silicon substrate 102 in organic solutions of CH₃CN or C₃H₇NO together with HF. An alternative approach is to chemically etch the silicon substrate 102 in a mixture of HF and HNO₃ to produce the porous silicon layer 104.

The fabrication process 500 also includes forming a seal layer 106 on the porous silicon layer 104 (block 504, stage 600(2) of FIG. 6A). As an example, the seal layer 106 can be obtained by high temperature annealing of the porous silicon layer 104 in an H₂ environment. High temperature annealing in H₂ will close pores on the porous silicon layer 104 and form a thin single crystal layer (the seal layer 106) with uniform surface. An alternative approach is to perform high temperature oxidation on the porous silicon layer 104. High temperature oxidation will form a thin single crystal layer (the seal layer 106) on the porous silicon layer 104 with an oxide layer on top of the seal layer 106. By removing the oxide layer, the seal layer 106 will be exposed.

The fabrication process 500 also includes forming an SBIL 110 on the seal layer 106 from strain balancing materials (e.g., SiGe) (block 506, stage 600(3) of FIG. 6A). As an example, the SBIL 110 can be obtained by epitaxial growth of the strain balancing materials on the seal layer 106. The seal layer 106 is a thin layer on the porous silicon layer 104. Thus, the seal layer 106 can stretch or compress freely. The SBIL 110 formed on the seal layer 106 is relaxed, which prevents formation of defects, such as dislocations in the SBIL 110, and results in the SBIL 110 with lower defect concentrations, even though lattice constant of the SBIL 110 is different from lattice constant of the seal layer 106.

The fabrication process 500 also includes forming an oxide layer 112 on the SBIL 110 (block 508, stage 600(4) of FIG. 6A). As an example, the oxide layer 112 can be obtained by thermal oxidation. During thermal oxidation, the oxide layer 112 (e.g., silicon dioxide (SiO₂)) is formed on the SBIL 110. The oxidation process can snowplow the Ge in the SBIL 110 into the seal layer 106. This process can convert the seal layer 106, which is single crystal silicon, to SiGe with the Ge coming from the SBIL 110. Thus, after thermal oxidation, there is no seal layer 106 remaining on the porous silicon layer 104. The SBIL 110 (e.g., SiGe) is directly on the porous silicon layer 104.

The fabrication process 500 further includes removing the oxide layer 112 from the SBIL 110 (block 510, stage 600(5) of FIG. 6B). As an example, the oxide layer 112 can be removed by wet etching or dry etching.

Next, the fabrication process 500 includes forming a high charge carrier mobility material layer 108 on the SBIL 110 (block 512, stage 600(6) of FIG. 6B). As an example, the high charge carrier mobility material layer 108 can be obtained by epitaxial growth of high charge carrier mobility materials on the SBIL 110. As described above, the SBIL 110 is relaxed and defect free. Thus, the quality of the high charge carrier mobility material layer 108 formed on the SBIL 110 can be enhanced. Additionally, the lattice constant of the SBIL 110 is closer to lattice constant of the high charge carrier mobility material layer 108 compared to lattice constant of Si. Thus, the high charge carrier mobility material layer 108 formed on the SBIL 110 may have lower defect concentrations compared with the high charge carrier mobility material layer 108 formed directly on Si. The high charge carrier mobility material layer 108 can be used to improve charge carrier mobility in different CMOS transistors. Following the fabrication process 500, standard CMOS process flow can be used to form various CMOS devices, such as transistors, from the semiconductor device 400.

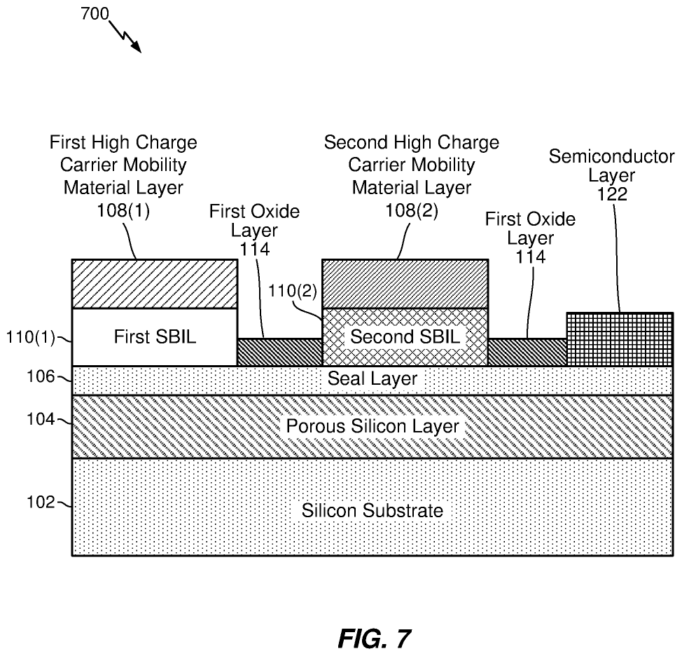

FIG. 7 illustrates another exemplary semiconductor device 700 with high charge carrier mobility materials formed on a silicon substrate with a porous silicon layer in accordance with certain aspects of the present disclosure. The semiconductor device 700 includes common elements with the semiconductor device 100A of FIG. 1A, the semiconductor device 100B of FIG. 1B, and the semiconductor device 400 of FIG. 4, which are referred to with common element numbers in FIG. 1A, FIG. 1B, FIG. 4, and FIG. 7, and thus will not be re-described herein.

The semiconductor device 700 shown in FIG. 7 includes different layers of materials on a silicon substrate 102. A porous silicon layer 104 is on the silicon substrate 102. A seal layer 106 is on the porous silicon layer 104. A first SBIL 110(1) is on a first portion of the seal layer 106. A second SBIL 110(2) is on a second portion of the seal layer 106. A semiconductor layer 122 (e.g., Si, Ge, SiGe, and SiC) is on a third portion of the seal layer 106. A first high charge carrier mobility material layer 108(1) is on the first SBIL 110(1). A second high charge carrier mobility material layer 108(2) is on the second SBIL 110(2). The first SBIL 110(1) and the second SBIL 110(2) may comprise same strain balancing materials. Alternatively, the first SBIL 110(1) and the second SBIL 110(2) may comprise different strain balancing materials. The first high charge carrier mobility material layer 108(1) and the second high charge carrier mobility material layer 108(2) may comprise same high charge carrier mobility materials. Alternatively, the first high charge carrier mobility material layer 108(1) and the second high charge carrier mobility material layer 108(2) may comprise different high charge carrier mobility materials. An oxide layer (e.g., a first oxide layer 114) may be deposited between the first SBIL 110(1) and the second SBIL 110(2) and between the second SBIL 110(2) and the semiconductor layer 122 on the seal layer 106 to isolate the first high charge carrier mobility material layer 108(1) from the second high charge carrier mobility material layer 108(2) and to isolate the second high charge carrier mobility material layer 108(2) from the semiconductor layer 122. Alternatively, other isolation structures, such as shallow trench isolation, may be used between the first SBIL 110(1) and the second SBIL 110(2) to isolate the first high charge carrier mobility material layer 108(1) from the second high charge carrier mobility material layer 108(2) and between the second SBIL 110(2) and the semiconductor layer 122 to isolate the second high charge carrier mobility material layer 108(2) from the semiconductor layer 122. The first high charge carrier mobility material layer 108(1), the second high charge carrier mobility material layer 108(2), and the semiconductor layer 122 can be used to form semiconductor devices for different applications based on material properties of the first high charge carrier mobility material layer 108(1), the second high charge carrier mobility material layer 108(2), and the semiconductor layer 122. Lattice constant of the first SBIL 110(1) is closer to lattice constant of the first high charge carrier mobility material layer 108(1) compared to lattice constant of Si. Lattice constant of the second SBIL 110(2) is closer to lattice constant of the second high charge carrier mobility material layer 108(2) compared to the lattice constant of Si. Thus, the first high charge carrier mobility material layer 108(1) formed on the first SBIL 110(1) and the second high charge carrier mobility material layer 108(2) formed on the second SBIL 110(2) may have lower defect concentrations compared with the first high charge carrier mobility material layer 108(1) and the second high charge carrier mobility material layer 108(2) formed directly on Si. By employing different strain balancing materials, different high charge carrier mobility materials can be used in the first high charge carrier mobility material layer 108(1) and the second high charge carrier mobility material layer 108(2) to form different CMOS transistors. Additional high charge carrier mobility material layers may be deposited on the first high charge carrier mobility material layer 108(1) or the second high charge carrier mobility material layer 108(2) to form a variety of semiconductor devices, such as bipolar junction transistors (BJT) and heterojunction bipolar transistors (HBT).

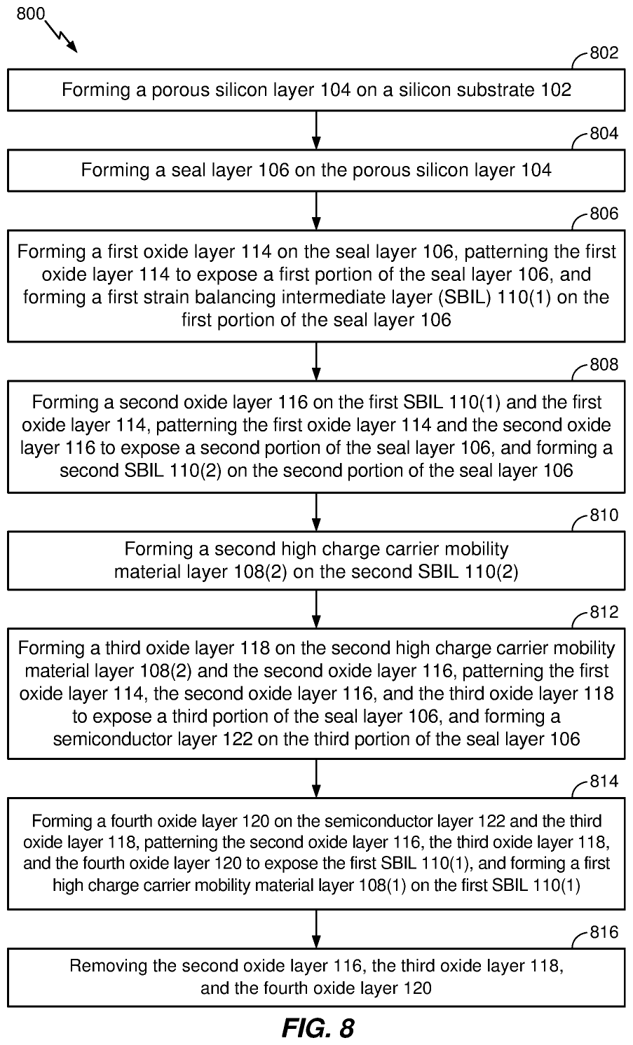

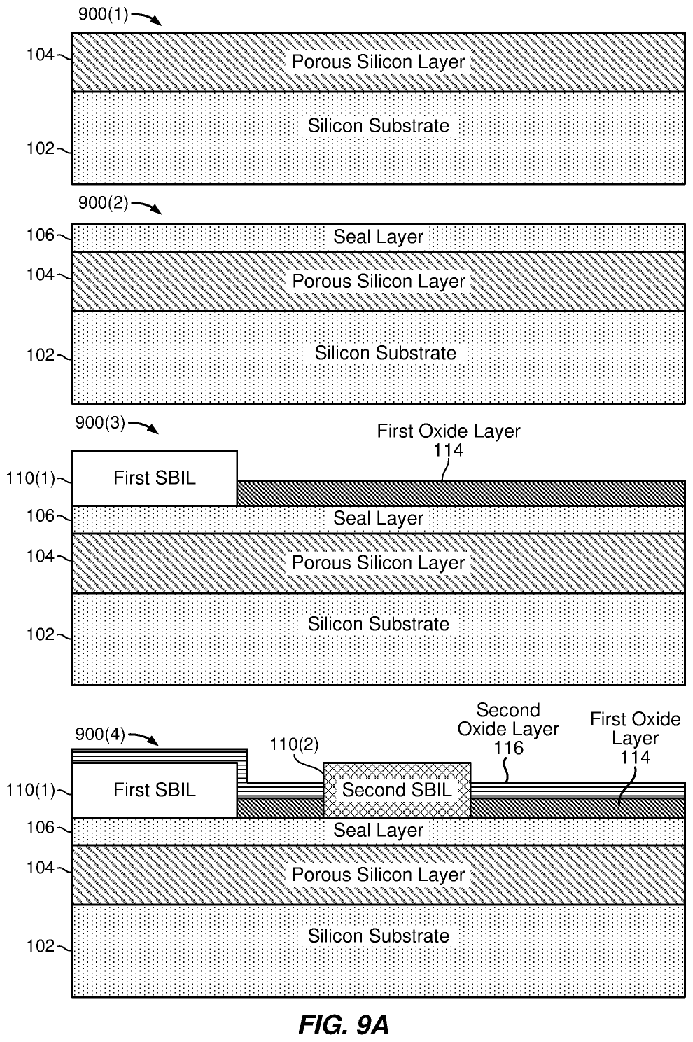

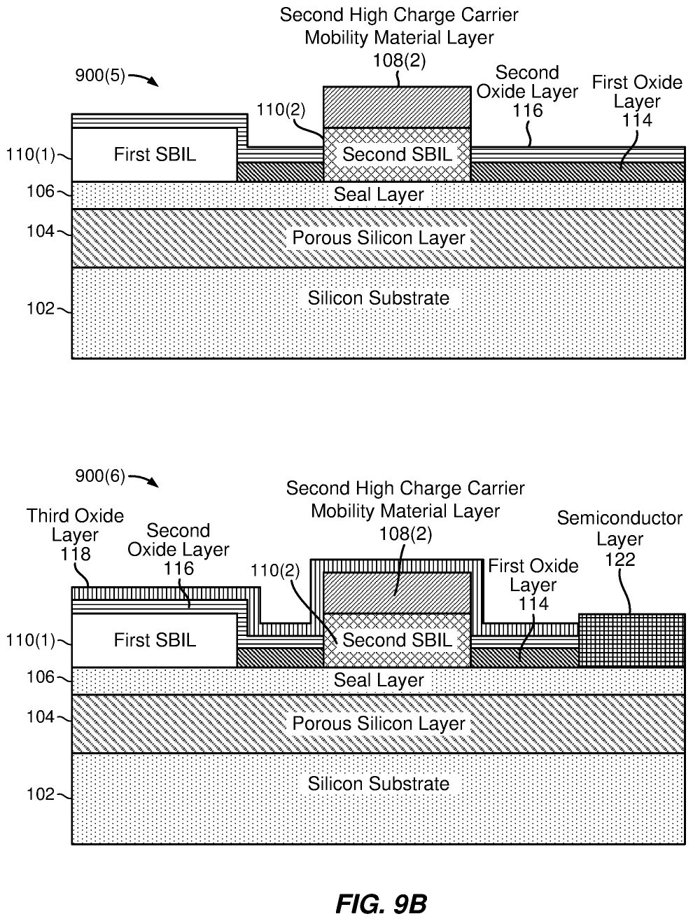

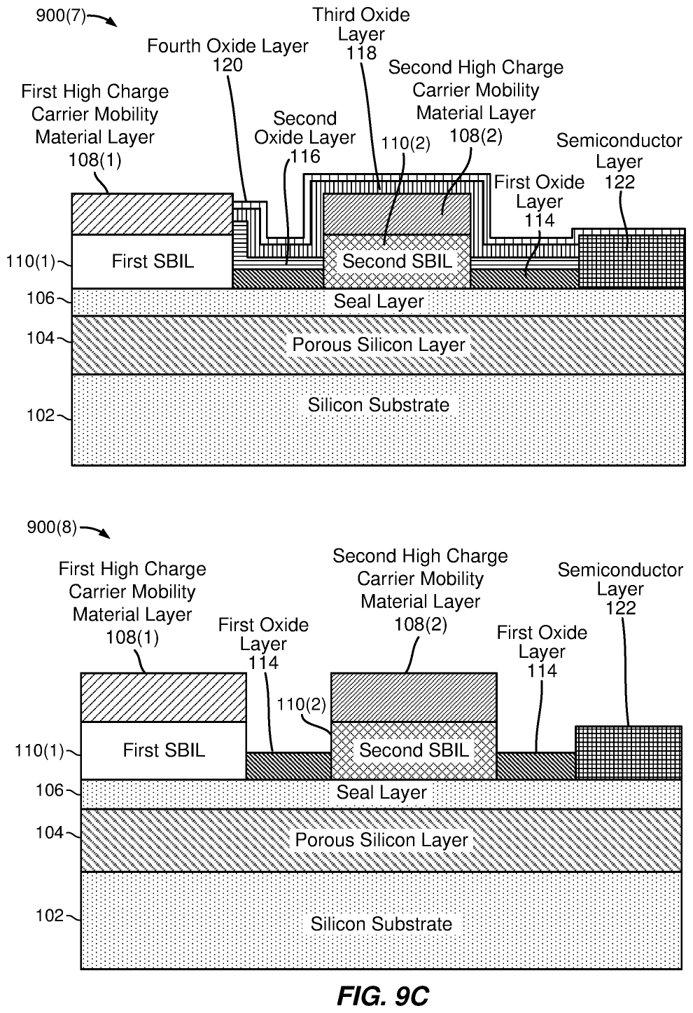

FIG. 8 illustrates an exemplary fabrication process 800 for the semiconductor device 700 in FIG. 7 in accordance with certain aspects of the present disclosure. FIGS. 9A-9C provide cross-sectional diagrams of the semiconductor device 700 of FIG. 7 illustrating respective stages 900(1)-900(8) of the fabrication process 800 in FIG. 8. The cross-sectional diagrams illustrating the semiconductor device 700 in FIGS. 9A-9C will be discussed in conjunction with the discussion of the exemplary steps in the fabrication process 800 in FIG. 8.

In this regard, the fabrication process 800 in FIG. 8 includes forming a porous silicon layer 104 on a single crystal silicon substrate 102 (block 802, stage 900(1) of FIG. 9A). As an example, the porous silicon layer 104 can be obtained by electrochemical etching of the silicon substrate 102 in organic solutions of CH₃CN or C₃H₇NO together with HF. An alternative approach is to chemically etch the silicon substrate 102 in a mixture of HF and HNO₃ to produce the porous silicon layer 104.

The fabrication process 800 also includes forming a seal layer 106 on the porous silicon layer 104 (block 804, stage 900(2) of FIG. 9A). As an example, the seal layer 106 can be obtained by high temperature annealing of the porous silicon layer 104 in an H₂ environment. High temperature annealing in H₂ will close pores on the porous silicon layer 104 and form a thin single crystal layer (the seal layer 106) with uniform surface. An alternative approach is to perform high temperature oxidation on the porous silicon layer 104. High temperature oxidation will form a thin single crystal layer (the seal layer 106) on the porous silicon layer 104 with an oxide layer on top of the seal layer 106. By removing the oxide layer, the seal layer 106 will be exposed.

The fabrication process 800 also includes forming a first oxide layer 114 on the seal layer 106. Alternatively, other hard mask layers, such as a silicon nitride layer, can be used instead of the first oxide layer 114. As an example, the first oxide layer 114 can be obtained by chemical vapor deposition, such as plasma enhanced chemical vapor deposition (PECVD). After deposition of the first oxide layer 114, the first oxide layer 114 can be patterned by etching (e.g., wet etching) to expose a first portion of the seal layer 106. A first SBIL 110(1) can be formed on the first portion of the seal layer 106 from strain balancing materials (e.g., SiGe and SiC) (block 806, stage 900(3) of FIG. 9A). As an example, the first SBIL 110(1) can be obtained by selective epitaxial growth of the strain balancing materials on the first portion of the seal layer 106. The selective epitaxial growth of the strain balancing materials can prevent the strain balancing materials from growing on the first oxide layer 114. The seal layer 106 is a thin layer on the porous silicon layer 104. Thus, the seal layer 106 can stretch or compress freely. The first SBIL 110(1) formed on the seal layer 106 is relaxed, which prevents formation of defects, such as dislocations in the first SBIL 110 (1), and results in the first SBIL 110(1) with lower defect concentrations, even though lattice constant of the first SBIL 110(1) is different from lattice constant of the seal layer 106.

The fabrication process 800 also includes forming a second oxide layer 116 on the first SBIL 110(1) and the first oxide layer 114, patterning the first oxide layer 114 and the second oxide layer 116 to expose a second portion of the seal layer 106, and forming a second SBIL 110(2) on the second portion of the seal layer 106 from strain balancing materials (e.g., SiGe and SiC) (block 808, stage 900(4) of FIG. 9A). Alternatively, other hard mask layers, such as a silicon nitride layer, can be used instead of the second oxide layer 116. As an example, the second oxide layer 116 can be obtained on the first SBIL 110(1) and the first oxide layer 114 by chemical vapor deposition, such as PECVD. The first oxide layer 114 and the second oxide layer 116 can be patterned by etching (e.g., wet etching) to expose the second portion of the seal layer 106. The second SBIL 110(2) can be obtained by selective epitaxial growth of the strain balancing materials on the second portion of the seal layer 106. The selective epitaxial growth of the strain balancing materials can prevent the strain balancing materials from growing on the second oxide layer 116. The first SBIL 110(1) and the second SBIL 110(2) may comprise the same strain balancing materials. Alternatively, the first SBIL 110(1) and the second SBIL 110(2) may comprise different strain balancing materials. The seal layer 106 is a thin layer on the porous silicon layer 104. Thus, the seal layer 106 can stretch or compress freely. The second SBIL 110(2) formed on the seal layer 106 is relaxed, which prevents formation of defects, such as dislocations in the second SBIL 110(2), and results in the second SBIL 110(2) with lower defect concentrations, even though lattice constant of the second SBIL 110(2) is different from the lattice constant of the seal layer 106.

The fabrication process 800 also includes forming a second high charge carrier mobility material layer 108(2) on the second SBIL 110(2) (block 810, stage 900(5) of FIG. 9B). As an example, the second high charge carrier mobility material layer 108(2) can be obtained by selective epitaxial growth of high charge carrier mobility materials on the second SBIL 110(2). The selective epitaxial growth of the high charge carrier mobility materials can prevent the high charge carrier mobility materials from growing on the second oxide layer 116. As described above, the second SBIL 110(2) is relaxed and defect free. Thus, the quality of the second high charge carrier mobility material layer 108(2) formed on the second SBIL 110(2) can be enhanced. Additionally, the lattice constant of the second SBIL 110(2) is closer to lattice constant of the second high charge carrier mobility material layer 108(2) compared to lattice constant of Si. Thus, the second high charge carrier mobility material layer 108(2) formed on the second SBIL 110(2) may have lower defect concentrations compared with the second high charge carrier mobility material layer 108(2) formed directly on Si. The second high charge carrier mobility material layer 108(2) can be used to improve charge carrier mobility in different CMOS transistors.

The fabrication process 800 also includes forming a third oxide layer 118 on the second high charge carrier mobility material layer 108(2) and the second oxide layer 116, patterning the first oxide layer 114, the second oxide layer 116, and the third oxide layer 118 to expose a third portion of the seal layer 106, and forming a semiconductor layer 122 on the third portion of the seal layer 106 (block 812, stage 900(6) of FIG. 9B). Alternatively, other hard mask layers, such as a silicon nitride layer, can be used instead of the third oxide layer 118. As an example, the third oxide layer 118 can be obtained on the second high charge carrier mobility material layer 108(2) and the second oxide layer 116 by chemical vapor deposition, such as PECVD. The first oxide layer 114, the second oxide layer 116, and the third oxide layer 118 can be patterned by etching (e.g., wet etching) to expose the third portion of the seal layer 106. The semiconductor layer 122 can be obtained by selective epitaxial growth on the third portion of the seal layer 106. The selective epitaxial growth can prevent the semiconductor layer 122 from growing on the third oxide layer 118. The seal layer 106 is a thin layer on the porous silicon layer 104. Thus, the seal layer 106 can stretch or compress freely. The semiconductor layer 122 formed on the seal layer 106 is relaxed, which prevents formation of defects, such as dislocations in the semiconductor layer 122, and results in the semiconductor layer 122 with lower defect concentrations, even though lattice constant of the semiconductor layer 122 may be different from the lattice constant of the seal layer 106.

The fabrication process 800 further includes forming a fourth oxide layer 120 on the semiconductor layer 122 and the third oxide layer 118, patterning the second oxide layer 116, the third oxide layer 118, and the fourth oxide layer 120 to expose the first SBIL 110(1), and forming a first high charge carrier mobility material layer 108(1) on the first SBIL 110(1) (block 814, stage 900(7) of FIG. 9C). Alternatively, other hard mask layers, such as a silicon nitride layer, can be used instead of the fourth oxide layer 120. As an example, the fourth oxide layer 120 can be obtained on the semiconductor layer 122 and the third oxide layer 118 by chemical vapor deposition, such as PECVD. The second oxide layer 116, the third oxide layer 118, and the fourth oxide layer 120 can be patterned by etching (e.g., wet etching) to expose the first SBIL 110(1). The first high charge carrier mobility material layer 108(1) can be obtained by selective epitaxial growth of high charge carrier mobility materials on the first SBIL 110(1). The selective epitaxial growth of the high charge carrier mobility materials can prevent the high charge carrier mobility materials from growing on the fourth oxide layer 120. The first high charge carrier mobility material layer 108(1) and the second high charge carrier mobility material layer 108(2) may comprise the same high charge carrier mobility materials. Alternatively, the first high charge carrier mobility material layer 108(1) and the second high charge carrier mobility material layer 108(2) may comprise different high charge carrier mobility materials. As described above, the first SBIL 110(1) is relaxed and defect free. Thus, the quality of the first high charge carrier mobility material layer 108(1) formed on the first SBIL 110(1) can be enhanced. Additionally, the lattice constant of the first SBIL 110(1) is closer to lattice constant of the first high charge carrier mobility material layer 108(1) compared to the lattice constant of Si. Thus, the first high charge carrier mobility material layer 108(1) formed on the first SBIL 110(1) may have lower defect concentrations compared with the first high charge carrier mobility material layer 108(1) formed directly on Si. The first high charge carrier mobility material layer 108(1) can be used to improve charge carrier mobility in different CMOS transistors.

Next, the fabrication process 800 includes removing the second oxide layer 116, the third oxide layer 118, and the fourth oxide layer 120 (block 816, stage 900(8) of FIG. 9C). As an example, the second oxide layer 116, the third oxide layer 118, and the fourth oxide layer 120 can be removed by wet etching or dry etching. Following the fabrication process 800, standard CMOS process flow can be used to form various CMOS devices, such as transistors, from the semiconductor device 700.

The elements described herein are sometimes referred to as means for performing particular functions. In this regard, the silicon substrate 102 is sometimes referred to herein as “means for supporting a porous silicon layer.” The seal layer 106 is sometimes referred to herein as “means for sealing a porous silicon layer.” The SBIL 110 is sometimes referred to herein as “means for balancing strain.” According to a further aspect of the present disclosure, the aforementioned means may be any layer, module, or any apparatus configured to perform the functions recited by the aforementioned means.

The semiconductor device with high charge carrier mobility materials formed on a silicon substrate with a porous silicon layer for CMOS transistor applications according to certain aspects disclosed herein may be provided in or integrated into any electronic device. Examples, without limitation, include a set top box, an entertainment unit, a navigation device, a communication device, a fixed location data unit, a mobile location data unit, a global positioning system (GPS) device, a mobile phone, a cellular phone, a smart phone, a session initiation protocol (SIP) phone, a tablet, a phablet, a server, a computer, a portable computer, a mobile computing device, a wearable computing device (e.g., a smart watch, a health or fitness tracker, eyewear, etc.), a desktop computer, a personal digital assistant (PDA), a monitor, a computer monitor, a television, a tuner, a radio, a satellite radio, a music player, a digital music player, a portable music player, a digital video player, a video player, a digital video disc (DVD) player, a portable digital video player, an automobile, a vehicle component, avionics systems, and a drone.

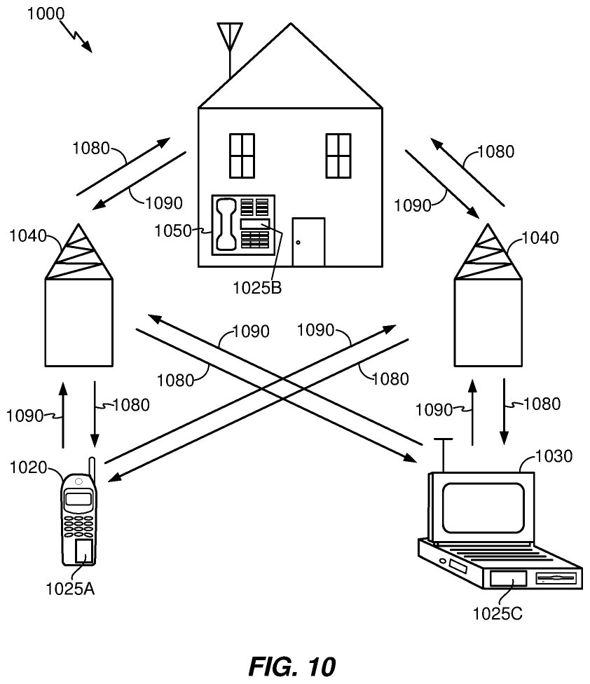

In this regard, FIG. 10 is a block diagram showing an exemplary wireless communication system 1000 in which an aspect of the present disclosure may be employed. For purposes of illustration, FIG. 10 shows three remote units 1020, 1030, and 1050 and two base stations 1040. It will be recognized that wireless communication systems may have many more remote units and base stations. Remote units 1020, 1030, and 1050 include integrated circuit (IC) devices 1025A, 1025C, and 1025B that may include the disclosed semiconductor device. It will be recognized that other devices may also include the disclosed semiconductor device, such as the base stations, switching devices, and network equipment. FIG. 10 shows forward link signals 1080 from the base stations 1040 to the remote units 1020, 1030, and 1050 and reverse link signals 1090 from the remote units 1020, 1030, and 1050 to the base stations 1040.

In FIG. 10, remote unit 1020 is shown as a mobile telephone, remote unit 1030 is shown as a portable computer, and remote unit 1050 is shown as a fixed location remote unit in a wireless local loop system. For example, a remote unit may be a mobile phone, a hand-held personal communication systems (PCS) unit, a portable data unit such as a PDA, a GPS enabled device, a navigation device, a set top box, a music player, a video player, an entertainment unit, a fixed location data unit, such as a meter reading equipment, or other communication device that stores or retrieves data or computer instructions, or combinations thereof. Although FIG. 10 illustrates remote units according to the certain aspects of the present disclosure, the disclosure is not limited to these exemplary illustrated units. Certain aspects of the present disclosure may be suitably employed in many devices, which include the disclosed semiconductor device.

Those of skill in the art will further appreciate that the various illustrative logical blocks, modules, circuits, and algorithms described in connection with the certain aspects disclosed herein may be implemented as electronic hardware, instructions stored in memory or in another computer readable medium and executed by a processor or other processing device, or combinations of both. The devices described herein may be employed in any circuit, hardware component, IC, or IC chip, as examples. Memory disclosed herein may be any type and size of memory and may be configured to store any type of information desired. To clearly illustrate this interchangeability, various illustrative components, blocks, modules, circuits, and steps have been described above generally in terms of their functionality. How such functionality is implemented depends upon the particular application, design choices, and/or design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the certain aspects disclosed herein may be implemented or performed with a processor, a Digital Signal Processor (DSP), an Application Specific Integrated Circuit (ASIC), a Field Programmable Gate Array (FPGA) or other programmable logic device, discrete gate or transistor logic, discrete hardware components, or any combination thereof designed to perform the functions described herein. A processor may be a microprocessor, but in the alternative, the processor may be any conventional processor, controller, microcontroller, or state machine. A processor may also be implemented as a combination of computing devices (e.g., a combination of a DSP and a microprocessor, a plurality of microprocessors, one or more microprocessors in conjunction with a DSP core, or any other such configuration).

The aspects disclosed herein may be embodied in hardware and in instructions that are stored in hardware, and may reside, for example, in Random Access Memory (RAM), flash memory, Read Only Memory (ROM), Electrically Programmable ROM (EPROM), Electrically Erasable Programmable ROM (EEPROM), registers, a hard disk, a removable disk, a CD-ROM, or any other form of computer readable medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a remote station. In the alternative, the processor and the storage medium may reside as discrete components in a remote station, base station, or server.

It is also noted that the operational steps described in any of the exemplary aspects herein are described to provide examples and discussion. The operations described may be performed in numerous different sequences other than the illustrated sequences. Furthermore, operations described in a single operational step may actually be performed in a number of different steps. Additionally, one or more operational steps discussed in the exemplary aspects may be combined. It is to be understood that the operational steps illustrated in the flowchart diagrams may be subject to numerous different modifications as will be readily apparent to one of skill in the art. Those of skill in the art will also understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples and designs described herein, but is to be accorded the widest scope consistent with the principles and features disclosed herein.

What is claimed is:

1. A semiconductor device, comprising:
a silicon substrate;
a porous silicon layer on the silicon substrate;
a seal layer on the porous silicon layer;
a first strain balancing intermediate layer and a second strain balancing intermediate layer, wherein the first strain balancing intermediate layer is on a first portion of the seal layer and the second strain balancing intermediate layer is on a second portion of the seal layer; and
a first high charge carrier mobility material layer and a second high charge carrier mobility material layer, wherein the first high charge carrier mobility material layer is on the first strain balancing intermediate layer and the second high charge carrier mobility material layer is on the second strain balancing intermediate layer.

2. The semiconductor device of claim 1, wherein the first strain balancing intermediate layer and the second strain balancing intermediate layer comprise at least one of Silicon Germanium (SiGe), Silicon Carbide (SiC), and alloys of silicon and III-V materials.

3. The semiconductor device of claim 1, wherein the first high charge carrier mobility material layer and the second high charge carrier mobility material layer comprise at least one of Germanium (Ge) and III-V materials.

4. The semiconductor device of claim 1, wherein a difference between a lattice constant of the first strain balancing intermediate layer and a lattice constant of the first high charge carrier mobility material layer is smaller than a difference between a lattice constant of silicon and the lattice constant of the first high charge carrier mobility material layer.

5. The semiconductor device of claim 1, wherein a difference between a lattice constant of the second strain balancing intermediate layer and a lattice constant of the second high charge carrier mobility material layer is smaller than a difference between a lattice constant of silicon and the lattice constant of the second high charge carrier mobility material layer.

6. The semiconductor device of claim 1, wherein the seal layer comprises single crystal silicon.

7. The semiconductor device of claim 1, wherein a lattice constant of the seal layer is different from a lattice constant of the first strain balancing intermediate layer and a lattice constant of the second strain balancing intermediate layer.

8. The semiconductor device of claim 1, wherein the first strain balancing intermediate layer comprises SiGe and the first high charge carrier mobility material layer comprises high charge carrier mobility materials with a lattice constant higher than a lattice constant of silicon, and wherein the second strain balancing intermediate layer comprises SiC and the second high charge carrier mobility material layer comprises high charge carrier mobility materials with a lattice constant lower than the lattice constant of silicon.

9. The semiconductor device of claim 1, further comprising an oxide layer between the first strain balancing intermediate layer and the second strain balancing intermediate layer on the seal layer.

10. The semiconductor device of claim 1 integrated into a device selected from the group consisting of: a set top box; an entertainment unit; a navigation device; a communication device; a fixed location data unit; a mobile location data unit; a global positioning system (GPS) device; a mobile phone; a cellular phone; a smart phone; a session initiation protocol (SIP) phone; a tablet; a phablet; a server; a computer; a portable computer; a mobile computing device; a wearable computing device; a desktop computer; a personal digital assistant (PDA); a monitor; a computer monitor; a television; a tuner; a radio; a satellite radio; a music player; a digital music player; a portable music player; a digital video player; a video player; a digital video disc (DVD) player; a portable digital video player; an automobile; a vehicle component; avionics systems; and a drone.
